(19) United States
(12) Patent Application Publication
(10) Pub. No.: US 2026/0293060 A1
(43) Pub. Date: Sep. 24, 2026

(54) ADDITIVELY MANUFACTURED, GEOMETRICALLY SYMMETRIC FLOW MANIFOLD, COOLING APPARATUS INCLUDING THE FLOW MANIFOLD, AND ELECTRONIC COMPONENT INCLUDING THE COOLING APPARATUS

(71) Applicant: HRL Laboratories, LLC, Malibu, CA (US)

(72) Inventors: Christopher Roper, Thousand Oaks, CA (US); Jeremy Orosco, Canoga Park, CA (US); Adam Gross, Santa Monica, CA (US); David Smith, Newbury Park, CA (US); Ethan Schlocker, Los Angeles, CA (US)

(21) Appl. No.: 19/332,898

(22) Filed: Sep. 18, 2025

Related U.S. Application Data
(60) Provisional application No. 63/775,933, filed on Mar. 21, 2025.

(51) Int. Cl. H05K 7/20

(52) U.S. Cl. CPC H05K 7/20772

(57) ABSTRACT

A cooling apparatus including a flow manifold and a finned plate having a base plate and a microchannel array, and a cooling system including the cooling apparatus are provided. The flow manifold is fabricated utilizing additive manufacturing and includes a multiscale hierarchical flow routing structure defined with respect to a balancing reference designed to reduce or minimize pressure drop and thermal resistance. The flow manifold incudes a balancing reference, a first level including first fluid passages open to an inlet, an output level including second fluid passages open to an outlet, and a second level including first fluid passages and second fluid passages. A volume of the inlet and a volume of the outlet are substantially equal with respect to the balancing reference. The cooling system further includes at least one pump and at least one heat exchanger in fluid communication with the flow manifold of the cooling apparatus.

### CROSS-REFERENCE TO RELATED APPLICATIONS

This application claims priority to and the benefit of Provisional Application No. 63/775,933, filed on Mar. 21, 2025, in the United States Patent and Trademark Office, the entire content of which is incorporated herein by reference.

### STATEMENT REGARDING FEDERALLY SPONSORED RESEARCH OR DEVELOPMENT

The present disclosure was made with U.S. Government support under DE-AR0001754 awarded by the Advanced Research Projects Agency-Energy (ARPA-E), U.S. Department of Energy. The U.S. Government has certain rights to the present disclosure.

### BACKGROUND

### 1. Field

One or more aspects of embodiments of the present disclosure relate to cooling systems for high-heat flux devices, specifically focusing on additively manufactured cooling blocks for efficient removal of multi-kilowatt thermal loads from chip-scale surface areas with less than forty Kelvin temperature difference.

### 2. Description of Related Art

Existing cooling solutions may be limited by high manufacturing costs, effective heat removal capacity, high energy cost to remove heat, and/or geometries that are difficult to produce. The present disclosure improves upon these limitations by enabling additively manufactured cooling blocks with a finned plate and complex flow manifold configurations. The benefits of microchannel cooling have been described previously, and manifolded microchannel heat exchanger designs are known to reduce pressure drop.

The following references are further provided and the entire contents of each of which are incorporated herein by reference:
D. B. Tuckerman and R. F. W. Pease, IEEE Electronic Device Letters, vol. EDL-2, no. 5, pp. 126-129 (1981).
M. A. Arie, et al., International Journal of Heat and Mass Transfer, vol. 81, pp. 478-489 (2015).

The present disclosure is related to the following U.S. patent documents issued to HRL: U.S. Pat. No. 11,680,756 and U.S. Patent Publication No. 2025/0071936 and the entire content of each of which is hereby incorporated by reference.

The preceding information disclosed in this Background section is only for enhancement of understanding of the background and related art of the disclosure and therefore it may contain information that does not constitute prior art.

### SUMMARY

One or more aspects of embodiments of the present disclosure are directed toward an additively manufactured, geometrically symmetric flow manifold and a cooling apparatus including the flow manifold for efficient removal of multi-kilowatt thermal loads from chip-scale surface areas. This present disclosure entails a heat sink including a finned plate attached to the flow manifold that includes symmetric multiscale hierarchically interlaced flow routing, or multiscale hierarchical flow routing defined with respect to a balancing reference.

The disclosure further enables modular integration into scalable thermal management systems, including those used in AI data centers, aerospace platforms, and/or high-power photonics. The symmetric manifold design ensures uniform coolant distribution, which is desired or even critical for minimizing thermal gradients and enhancing device reliability.

Additional aspects will be set forth in part in the description which follows and, in part, will be apparent from the description, or may be learned by practice of the presented embodiments of the disclosure.

One or more embodiments of the present disclosure provide a cooling apparatus including: a finned plate including a base plate and a microchannel array; and a flow manifold including: a first level including first fluid passages open to an inlet; an output level including second fluid passages open to an outlet; a second level including first fluid passages and second fluid passages; and a balancing reference, a volume of the inlet and a volume of the outlet being substantially equal with respect to the balancing reference.

In one or more embodiments, the microchannel array includes a plurality of fins, the fins being connected to and extending from a surface of the base plate, adjacent ones of the fins being spaced apart from each other to form a plurality of microchannels between the fins, one of the microchannels being between each adjacent two of the fins, and an interior of the flow manifold is in fluid communication with the microchannels.

In one or more embodiments, the microchannels extend in a direction parallel to each other and perpendicular to a direction of extension of a plurality of first fluid passages in a lowest level of the flow manifold.

In one or more embodiments, a width of the microchannels is about 1 micrometer (μm) to about 500 μm.

In one or more embodiments, the fins include a thermally conductive material and have a highest thermal conductivity axis with a conductivity of at least about 400 watt per meter degree K (W/m-K), a thickness of the fins is about 1 μm to about 500 μm, and a height of the fins is about 200 μm to about 5000 μm.

In one or more embodiments, the base plate includes aluminum, carbon, copper, gold, molybdenum, nitrogen, palladium, platinum, silicon, silver, tungsten, graphite, diamond, an alloy thereof, a compound thereof, and any suitable combination thereof, a thickness of the base plate is about 10 μm to about 2000 μm, and a shear modulus of the base plate is about 10 megapascal (MPa) to about 300 gigapascal (GPa).

In one or more embodiments, the each of the first fluid passages in the second level is in fluid communication with the inlet via the first fluid passages in first level, each of the second fluid passages in the second level is in fluid communication with the outlet via the second fluid passages in the first level, the first fluid passages in the second level are greater in number than the first fluid passages in the first level, the first fluid passages in the first level extend in a first direction, the first fluid passages in the second level extend in a second direction, the second direction perpendicular to and crossing the first direction, each of the first fluid passages in the second level extend under the first fluid passages in the first level.

In one or more embodiments, the first fluid passages in the second level are interleaved with the second fluid passages in the second level.

In one or more embodiments, the flow manifold includes a third level including a plurality of first fluid passages and a plurality of second fluid passages, a number of the first fluid passages in the third level being greater than a number of the first fluid passages in the second level, each of the first fluid passages in the second level is in fluid communication with the inlet and at least one of the first fluid passages in the third level, and each of the second fluid passages in the second level is in fluid communication with the outlet and at least one of the second fluid passages in the third level.

In one or more embodiments, the flow manifold includes a forked flow manifold, and the first level is the output level, the first fluid passages include a central intake, two periphery intakes, and n median intakes, the central intake at a center of the first level, the periphery intakes at opposite ends of the first level, and each of the median intakes between the central intake and one of the periphery intake, the second fluid passages include n+2 outputs, each output between the central intake and one of the periphery intakes, and each having a width that is substantially equal, n is an integer from 0 to 10, the balancing reference is a plane of symmetry bisecting the central intake and parallel to a flow direction of the central intake, the width of each output is substantially equal to a width of the central intake, and about twice a width of any one periphery intake, each of the first fluid passages in the second level is in fluid communication with the central intake, the periphery intakes, the n median intakes, and each of the second fluid passages in the second level is in fluid communication with the n+2 outputs.

In one or more embodiments, the flow manifold is configured to provide symmetric flow distribution, and the flow manifold and the finned plate are modular and removably coupled.

In one or more embodiments, the cooling apparatus includes a compression gasket and each of the finned plate and the flow manifold includes a sealing groove.

In one or more embodiments, the flow manifold includes a thermal isolation layer between the inlet and the outlet, the thermal isolation layer including a gas-filled cavity, aerogel, or a low-conductivity polymer.

In one or more embodiments, the balancing reference includes a mirror plane of symmetry bisecting the flow manifold, the inlet and the outlet being mirrored through the mirror plane of symmetry.

In one or more embodiments, the balancing reference includes a rotational axis of symmetry about which the inlet and the outlet are arranged in a radially symmetric configuration.

One or more embodiments of the present disclosure provide a cooling system including: at least one cooling apparatus including a finned plate including a base plate and a microchannel array; and a flow manifold including: a first level including first fluid passages open to an inlet; an output level including second fluid passages open to an outlet; a second level including first fluid passages and second fluid passages; and a balancing reference, a volume of the inlet and a volume of the outlet being substantially equal with respect to the balancing reference, at least one pump; and at least one heat exchanger in fluid communication with the flow manifold of the cooling apparatus.

One or more embodiments of the present disclosure provide a cooling system including: an electronic component; a cooling apparatus according to the present disclosure on the electronic component; and a heat exchanger in fluid communication with the flow manifold of the cooling apparatus.

One or more embodiments of the present disclosure provide a cooling system including: a plurality of cooling apparatuses each according to the present disclosure; a shared coolant distributor configured to supply a coolant to each of the plurality of cooling apparatus; a controller configured to monitor and adjust coolant flow rates to each of the plurality of cooling apparatuses based on thermal load; and a heat exchanger in fluid communication with the shared coolant distributor.

In one or more embodiments, a coolant flows between the cooling apparatus and the heat exchanger and the coolant has a laminar flow.

One or more embodiments of the present disclosure provide a data center including: a plurality of electronic components; and at least one cooling system according to the present disclosure; wherein the plurality of cooling apparatuses are on the plurality of electronic components.

### BRIEF DESCRIPTION OF THE DRAWINGS

The features and advantages of embodiments of the present disclosure will be better understood by reference to the following detailed description if (e.g., when) considered in conjunction with the accompanying drawings.

FIG. 1A is a schematic perspective view of a cooling apparatus according to one or more embodiments of the present disclosure.

FIG. 1B is a partial cut-away view of a flow manifold according to one or more embodiments of the present disclosure.

FIG. 2A is a schematic view of a finned plate 20 according to one or more embodiments of the present disclosure.

FIG. 2B is an expanded view of area 2B of FIG. 2A.

FIG. 3A shows the flow direction in fluid passages in a second level of a flow manifold and a microchannel array 40 according to one or more embodiments of the present disclosure.

FIG. 3B is an expanded cross-sectional view of a microchannel from the perspective labeled 3B in FIG. 3A.

FIG. 4 is a schematic diagram of a balancing reference of a flow manifold according to one or more embodiments of the present disclosure.

FIG. 5 is a perspective view of a symmetric flow manifold according to one or more embodiments of the present disclosure.

FIG. 5A is a partial cut-away view of the symmetric flow manifold according to FIG. 5.

FIG. 6 is a perspective view of a symmetric flow manifold according to one or more embodiments of the present disclosure.

FIGS. 6A and 6B are each a cut-away perspective view of the symmetric flow manifold according to FIG. 6.

FIGS. 7-9 are charts of performance evaluations of a cooling apparatus according to the present disclosure.

FIG. 10 is a perspective view of a symmetric flow manifold according to one or more embodiments of the present disclosure.

### DETAILED DESCRIPTION

The following description sets forth one or more suitable example embodiments and details in order to provide a more thorough understanding of the present disclosure. However, the subject matter of the present disclosure may be embodied in many different forms, and is not limited to the embodiments and details set forth herein. All disclosed features may be replaced with comparable features serving the same, equivalent, or similar purpose, unless expressly stated otherwise. Features of one embodiment may be incorporated into other embodiments unless expressly stated otherwise.

In the drawings, the same or similar reference numerals refer to the same or similar elements throughout, and duplicative descriptions thereof may not be provided. The drawings are not necessarily drawn to scale, and thicknesses and dimensions of elements may be exaggerated for clarity.

Unless otherwise defined, all chemical names, technical and scientific terms, and terms defined in common dictionaries should be interpreted as having meanings consistent with the context of the related art and should not be interpreted in an ideal or overly formal sense.

As utilized herein, expressions such as “at least one of,” “one of,” “at least one selected from among,” and “selected from among,” if (e.g., when) preceding a list of elements, modify the entire list of elements and do not modify the individual elements of the list. As utilized herein, the expressions “at least one of A, B, or C”, “one of A, B, C, or a combination thereof” and “one of A, B, C, and a combination thereof” refer to each component and a combination thereof (e.g., A; B; A and B; A and C; B and C; or A, B, and C). For example, “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As utilized herein, it is to be understood that the terms such as “including,” “includes,” “include,” “having,” “has,” “have,” “comprises,” “comprise,” and/or “comprising” are intended to indicate the existence of the features, numbers, steps, actions, components, parts, ingredients, materials, and/or one or more (e.g., any suitable) combinations thereof disclosed in the specification and are not intended to preclude the possibility that one or more other features, numbers, steps, actions, components, parts, ingredients, materials, and/or one or more (e.g., any suitable) combinations thereof may exist or may be added. The term “combination thereof may include a mixture, a laminate, a complex, a copolymer, an alloy, a blend, a reactant of constituents.

As utilized herein, singular forms such as “a,” “an,” and “the” are intended to include the plural forms as well, unless the context clearly indicates otherwise.

As utilized herein, the terms “use,” “using,” and “used” may be considered synonymous with the terms “utilize/utilization,” “utilizing,” and “utilized,” respectively.

In this context, “consisting essentially of” refers to that any additional components will not materially affect the chemical, physical, optical or electrical properties of the semiconductor film.

Furthermore, any claim element that does not explicitly recite a “means for” or “step for” in performing a function, is not to be interpreted as a “means” or “step” clause under 35 U.S.C. § 112 (f). The use of “step of” or “act of” in the claims herein is not intended to invoke the provisions of 35 U.S.C. § 112 (f).

It will be understood that if (e.g., when) an element (e.g., layer) is referred to as being “outside,” “inside,” “on,” “above,” “below,” “connected to,” or “coupled to” another element, it may be in direct contact with the other element, or one or more intervening elements may be present. In contrast, if (e.g., when) an element (e.g., layer) is referred to as being “directly” on, above, below, and/or the like. another element, no intervening elements are present. Terms describing spatial relationships between elements or features (such as “below,” “lower,” “under,” “above,” “upper,” and/or the like.) should be interpreted in the context of the device as a whole. For example, an element described as being “under” a second element could be alternatively described as being “above” the second element in an alternative orientation, if (e.g., when) such orientation is available.

Example embodiments of the present disclosure will be described with reference to the accompanying drawings. In the drawings, the same or similar reference numerals refer to the same or similar elements throughout, and duplicative descriptions thereof may not be provided the specification. The thickness of layers, films, panels, regions, and/or the like, are exaggerated for clarity. It will be understood that if (e.g., when) an element such as a layer, film, region, or substrate is referred to as being “on” another element, it can be directly on the other element or intervening element(s) may also be present. In contrast, if (e.g., when) an element is referred to as being “directly on” another element, there are no intervening elements present.

Herein, the use of the term “may,” if (e.g., when) describing embodiments of the present disclosure, refers to “one or more embodiments of the present disclosure.” In addition, the use of alternative language, such as “or,” if (e.g., when) describing embodiments of the present disclosure, refers to “one or more embodiments of the present disclosure” for each corresponding item listed. For example, “A or B” is construed to include A, B, A+B, and/or the like. Similarly, the term “and/or” includes any and all combinations of one or more of the associated listed items. The symbol “/” as utilized herein, may be interpreted as “and” or “or” according to the context. Also, the term “exemplary”, “preferred”, “preferable”, “preferably”, and/or the like is intended to refer to an example, embodiment, or illustration.

All references herein to the/our “invention”, “invented idea”, “our system”, “this system” (in context with “our system”), “proposed system”, “innovative method”, “inventive concept”, “method”, “this circuit”, “this architecture”, “this”, “the current invention”, and/or the like shall refer to one or more embodiments of present disclosure.

### INTRODUCTION

The present disclosure provides a flow manifold having symmetric multiscale hierarchically interlaced flow routing, or multiscale hierarchical flow routing structure defined with respect to a balancing reference, that leverages the heat exchangers and manifolds in U.S. Pat. No. 11,680,756 and U.S. Patent Publication No. 2025/0071936, with the important innovation of geometric strategies to symmetrize the design—or more generally, to define a balancing reference—to provide the cooling block-manifold interfacial flow uniformity required for the high-performance operation required by target applications. In contrast to the related art, which discloses asymmetric or otherwise non-symmetric manifold and heat exchanger configurations, the present disclosure introduces novel, physics-based design enhancements. For example, the designs of the present disclosure include thermal conductivity dependent fin heights, Poiseuille flowrate partitioning, optimal short-throw recirculation paths, multistage turbulence reduction, symmetric inlet/outlet configuration (e.g., forked inlet/outlet or hot outflow removed at sublevel), insulating materials selection for manifold fabrication (high-temperature acrylate resin), fin materials selection for thermal stress reduction (low coefficient of thermal expansion (CTE) combined with high compliance) in the finplate-heat source interface (copper impregnated graphite), configurations for reducing undesirable bypass flow within the gap between the fins and the manifold (elastomeric extrusions from fins, flat interfacing with o-ring groove depth optimization), and all-in-one (manifold+cooling block) design and production using additive manufacturing (LPBF, electrochemical additive manufacturing (ECAM), SLA, etc.) methods.

In terms of efficiency, an optimal or desired design provides minimal or reduced amount of required power input. Pressure drop is directly associated with this input power, and thus minimizing or reducing pressure drop is desirable.

In terms of performance, a reduced specific thermal resistance (i.e., inverse total heat transfer coefficient) enables the removal of large heat loads (typically in this case, multiple kilowatts) without a large rise in temperature across the heat transfer interface, and over relatively small areas (typically in this case, one kilowatt dissipated over less than three square centimeters). The thermal resistance of a single-phase liquid cooling block may include thermal resistance of solid conduction, thermal resistance of convection, thermal resistance of sensible heat gain, and/or thermal resistance of a thermal interface material between the heat source and the cooling block.

The present disclosure outperforms existing methods by providing highly efficient motivation of fluid through the cooling block, enabled by reduced or minimized recirculating paths through channels to reduce frictional pressure drop, multi-stage turbulence mitigation to reduce turbulent pressure drop, Poiseuille flow partitioning to improve flow/pressure distribution uniformity, reducing pressure drop extrema, and symmetric hierarchical manifolding (inlet/outlet configuration) to improve flow/pressure distribution uniformity, reducing pressure drop extrema.

Previous versions of this manifolding were generally asymmetric, and thus had imbalanced flow/pressure distribution leading to a lack of flow uniformity and gradient flowrate bias at the manifold-microchannel interface that is insufficient for meeting the performance demands of this application. For example, a single top level inlet and single top level outlet contributed to imbalances in flow and/or pressure distribution. The present disclosure improves on the previous versions by providing very low thermal resistance from coolant to heat source, enabled by: high inlet flow rates (enabled by low pressure drop, enabled by the preceding description) which reduce thermal resistance of sensible heat gain, fin heights optimized against thermal conductivity, optimized fin surface area utilized for thermal convection, which reduce solid conduction thermal resistance and thermal resistance of convection, low thermal crosstalk between cold inflow and hot outflow (low conductivity manifold materials and/or double sheet design) which maintains temperature difference thus providing a general reduction in thermal resistance, bypass flow mitigating measures (gasket groove depth optimization, elastomeric fin extrusions) to ensure flow fully penetrates into channels, reducing thermal resistance of convection and thermal resistance of sensible heat gain. For example, the thermal resistance of convection may be minimized or reduced by utilizing recirculating paths having very short length through the flow channels to eliminate a fully developed region as described by Tuckerman et al., where minimal characteristic width of the flow channels serves to reduce or prevent thermal resistance of convection.

The present disclosure improves on the previous versions by providing improved reliability, enabled by: reduced thermally-induced interfacial stress (enabled by low CTE, high compliance materials), lower channel flow velocities (enabled by fin height optimization) leading to less corrosion, multi-stage turbulence reduction leading to less corrosion, and seamless all-in-one construction (enabled by ECAM manufacturing), higher resistance to structural failure mode due to heat, pressure, and/or the like.

Our most recent performance assessment of a cooling block with these features produced a world-record microchannel cooling block performance curve defined by value pairings of input power and thermal resistance as described in more detail herein. That is, no other microchannel cooling block is presently known that provides these combined levels of performance and efficiency.

This invention applies to any application where thermal management of high heat load (multiple kilowatts) and/or high heat flux (hundreds of watts per square centimeter) producing devices is required under significant size, weight, and/or efficiency constraints. Commercial applications include but are not necessarily limited to: power electronics (power transistors, amplifiers, etc.), densely populated integrated circuits (ICs) used for computational tasks (CPUs and GPUs, in particular those used in AI datacenters), communications systems (radar, microwave, 5G, etc.), and high power laser applications (LIDAR), directed energy microwave systems, particle accelerator components (especially targets), aerothermal heating in high speed flight, fusion reactor walls and blankets, and radio detection and ranging (RADAR) systems.

The present disclosure is the combined result of rigorous physics-based design decisions and a long, substantial iterative “try and fail” development process. Although some work has been done previously investigating some aspects of efficient microchannel cooling blocks, most of these studies have considered theoretical extrapolations of the principles and thus were limited by a lack of iterative development. The preceding innovations, most of which are synergistic in their contribution to efficiency and/or performance, were not immediately obvious due to the need to combine theoretical investigations with the ground truth provided by lab testing and development. Many were arrived at only after the latter was addressed. The resulting validated performance of the invention demonstrates marketability toward thermal management of next-generation heat flux producing electronics beyond what was previously thought possible by microchannel cooling blocks.

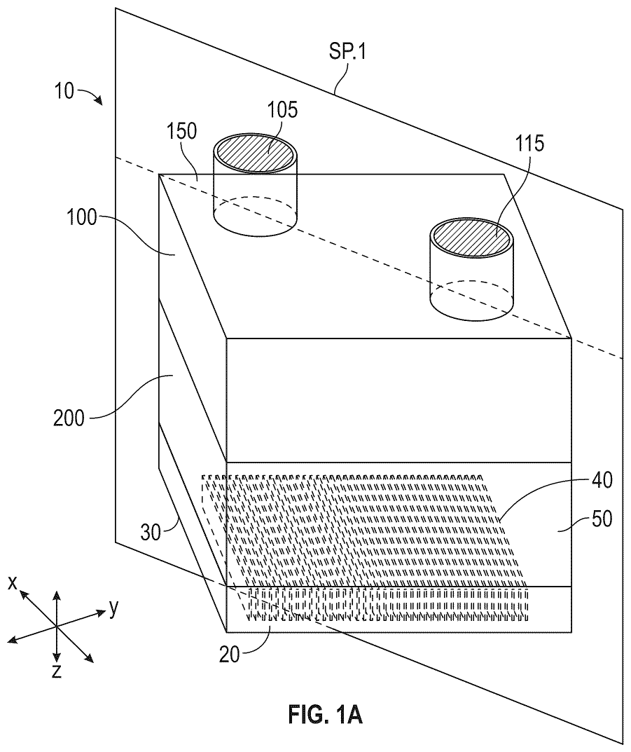

FIG. 1A shows a cooling apparatus 10 including a finned plate 20 and a flow manifold 50. The finned plate 20 includes a base plate 30 and a microchannel array 40, as described in more detail elsewhere herein. The finned plate 20 is coupled to the flow manifold 50 as described in more detail herein.

### Flow Manifold

According to one or more embodiments of the present disclosure, the flow manifold 50 may be configured to provide symmetric flow distribution. For example, flow manifold 50 is designed such that the inlet and outlet volumes, flow paths, and/or path dimensions are symmetrically arranged around a central balancing reference.

As used herein, a “balancing reference” refers to a geometric or functional construct—such as a plane, axis, point, or functional equivalent zone—about which the flow manifold is substantially symmetric in structure and/or function. In some embodiments, the balancing reference is a plane that bisects the flow manifold such that the volumes, flow paths, path dimensions, or flow resistances of a cool fluid inlet and a warm fluid outlet are substantially balanced or mirrored. This symmetrical arrangement may be used to ensure uniform flow distribution, reduce pressure gradients, and improve thermal performance across the flow manifold, the microchannel array, the finned plate, and the cooling apparatus. For example, the balancing reference may be a mirror plane, a rotational axis, or a central point that defines a balanced or mirrored configuration of flow paths, volumes, or flow resistances. However, the term is not limited to strict geometric symmetry. In certain embodiments, the balancing reference may encompass functionally symmetric or quasi-symmetric arrangements, including laterally branched or asymmetrically structured manifolds that achieve substantially uniform flow distribution, balanced pressure drops, or equivalent thermal performance across the cooling interface.

In one or more embodiments, the balancing reference may be a mirror plane of symmetry bisecting the flow manifold, and the inlet and the outlet may be reflected (e.g., mirrored) through the mirror plane of symmetry. For example, the flow manifold 50 may have in an upper region (e.g., furthest away from the microchannel array 40) lateral branching to split the flow laterally and provide symmetrical flow distribution. That is, the flow manifold 50 may include, in the upper region (e.g., furthest from the microchannel array 40), lateral branching that splits the flow laterally to promote balanced distribution prior to entering a hierarchical stack of flow channels.

In one or more embodiments, the balancing reference may be a rotational axis of symmetry about which the inlet and the outlet are arranged in a radially symmetric configuration.

In one or more embodiments, the flow manifold may include a central inlet and a plurality of peripheral outlets arranged symmetrically around the central inlet with respect to the balancing reference.

In one or more embodiments, the flow manifold includes a radial or spiral flow geometry, and the microchannel array is arranged in a concentric or annular configuration.

In one or more embodiments, the flow manifold 50 may be manufactured by a suitable additive manufacturing process (e.g., 3D printing). Some examples of the additive manufacturing process include vat polymerization (e.g., stereolithography; digital light processing; scan, spin, and selectively photocure; continuous liquid interface production), powder bed fusion (e.g., selective laser sintering, direct metal laser sintering, selective laser melting, selective heat sintering, multi-jet fusion), binder jetting (e.g., 3DP, ExOne, VoxelJet, desktop metal), material jetting (e.g., Polyjet, Smooth Curvatures Printing, Multijet Modeling, Projet), sheet lamination (e.g., laminated object manufacture, selective deposition lamination, ultrasonic additive manufacturing), material extrusion (e.g., fused filament fabrication, fused deposition modeling, direct ink write), directed energy deposition (e.g., laser metal deposition, laser energy net shaping, direct metal depositions, laser engineered net shaping), hybrids of multiple additive manufacturing methods, and/or hybrids of additive and subtractive manufacturing methods. Subtractive manufacturing may refer to, as some examples, machining or computer numerical control (CNC) machining. In one or more embodiments, the manifold may be fabricated utilizing a hybrid process combining laser powder bed fusion (LPBF) for structural features and electrochemical additive manufacturing (ECAM) for fine-resolution internal channels. This hybrid approach enables high-density microchannel integration with minimal post-processing.

One or more suitable post-processing treatments may be used to remove unwanted material after additive manufacturing and provide for a better interior surface finish, e.g., electrochemical etching, flushing with fluid and abrasive media, vibration, or a combination thereof. The manifold 50 and the finned plate 20 may be fabricated in two or more parts and then bonded or gasketed together as described in more detail herein. The manifold 50 and the finned plate 20 may be manufactured as a single piece using additive manufacturing (e.g. LBPF, SLS, ECAM, etc.) methods to obtain single-piece construction.

According to one or more embodiments, the flow manifold 50 and/or the finned plate 20 may be modular components and may be removably coupled or connected to each other.

Performance efficiency of the cooling apparatus 10 is improved by minimizing distances between inflow and outflow regions at an interface of the flow manifold 50 and the finned plate 20, as described in more detail herein. The flow manifold 50 may have single walls that are non-thermally conductive or may have double walls including two solid layers coupled only at the top and/or bottom and nowhere in between to provide a continuous region of air separating the two layers. The single or double walls and the region of air are of minimum thickness as allowed by the additive material and its manufacturing process. These strategies ensure that the distance traveled by a coolant in a fluid passage (e.g., between exiting the manifold as cold inflow and reentering the manifold as hot outflow) is a short flow path and is minimized (reduced) to minimize (reduce) pressure drop and improve heat transfer. Minimizing wall and gap thicknesses provides short flow paths are as short as possible, which minimizes (reduces) frictional pressure loss and maximizes heat transfer due to maximization of developing regions.

Flow manifold 50 may be or include a polymer, resin, metals, ceramics, glasses, composites, and/or a (e.g., any suitable) combination thereof. A low-thermal conductivity, high-temperature resin (e.g., with heat deflection temperature specification determined by application temperature boundary conditions) may be used in additive manufacture of the manifold to thermally isolate the cold inflow from the warm outflow (prevents preheating and preserves maximal temperature difference).

The double wall construction may be used in the flow manifold 50 and may be manufactured from high thermal conductivity materials like metals, such that everywhere the cold inflow and hot outflow are oriented in adjacent cavities, the two are separated by a gap region with a gas state (e.g., air), for example cold inflow/metal manifold wall/air/metal manifold wall/hot outflow. Regions between the two walls may include air, an inert gas, a noble gas, aerogel, porous foam insulation, mechanical spacer features (e.g., periodic posts or spars), hollow microspheres (e.g. hollow glass microspheres), and/or a (e.g., any suitable) combination thereof. In some embodiments, the air gap (or gap region) may be filled with a low-conductivity gas such as xenon or krypton to further reduce thermal bridging. Alternatively, the gap may be evacuated to create a vacuum-insulated barrier.

In one or more embodiments, the flow manifold 50 includes a thermal isolation layer between the inlet and the outlet, and the thermal isolation layer may include a gas-filled cavity, an aerogel, or a low-conductivity polymer.

In one or more embodiments, the cooling apparatus 10 includes at least one flow control element within the flow manifold 50 and the flow control element includes at least one valve, at least one variable orifice, and/or at least one deformable membrane configured to dynamically adjust flow distribution.

FIG. 1A shows that flow manifold 50 includes a first level 100, a second level 200, and an output level 150 in the first level 100, but the present disclosure is not limited thereto. In one or more embodiments, the output level may be in any level of the flow manifold, e.g., the first level, a second level, etc. The first level 100 includes a cool fluid inlet 105 and a warm fluid outlet 115. Here, reference to “warm” and “cool” is only for ease of explanation, and terms can be replaced by “first” and “second” without affecting the disclosure. In one or more embodiments, the flow manifold 50 includes a plurality of (at least one) cool fluid inlets and a plurality of (at least one) warm fluid outlets.

FIG. 1A shows a plane of symmetry SP.1 of flow manifold 50 that serves as an example of, and provides a more concrete geometric meaning to, the balancing reference of the present disclosure. The plane of symmetry SP.1 bisects flow manifold 50 and divides its structures to be mirrored on either side of SP.1. For example, SP.1 bisects each of the cool fluid inlet 105 and the warm fluid outlet 115 and reflects each of the cool fluid inlet 105 and the warm fluid outlet 115 into itself. A flow rate and/or volume of the cool fluid inlet 105 and a flow rate and/or volume of the warm fluid outlet 115 may be substantially equal with respect to SP.1.

FIG. 1B shows a partial cut-away view of the flow manifold 50 with the outer housing in line form. The first level 100 of flow manifold 50 includes a first fluid passage 125 in fluid communication with the cool fluid inlet 105 and (e.g., the output level 150 includes) a second fluid passage 135 in fluid communication with the warm fluid outlet 115.

FIG. 1B shows the second level 200 of flow manifold 50 having first fluid passages 225 each in fluid communication with the first fluid passage 125 and the cool fluid inlet 105, and second fluid passages 235 each in fluid communication with the second fluid passage 135 and the warm fluid outlet 115.

In one or more embodiments, the first fluid passages 225 in the second level 200 may be greater in number than the first fluid passage(s) 125 in the first level.

In one or more embodiments, the first fluid passages 125 in the first level may extend in a first direction. The first fluid 225 passages in the second level may extend in a second direction, the second direction being substantially perpendicular to and crossing the first direction.

In one or more embodiments, each of the first fluid passages 225 in the second level 200 may extend under the first fluid passage(s) 125 in the first level 100.

In one or more embodiments, the first fluid passages 225 in the second level may be interleaved with the second fluid passages 235 in the second level 200.

In FIG. 1A, the inlet 105 and outlet 115 are shown as protruding (e.g., extending) from the first level 100 in a direction parallel to the flow direction of the fluid(s) through the flow manifold 50 (e.g., parallel to a longitudinal direction of the cooling apparatus 10 represented by the z-direction), but the present disclosure is not limited thereto. For example, the inlet 105 and/or the outlet 115 may protrude (e.g., extend) from the flow manifold 50 in a direction perpendicular to the flow direction of the fluids through the flow manifold 50 (e.g., the x-direction). Other suitable arrangements of the inlet 105 and/or the outlet 115 in the flow manifold 50 are contemplated, such an inlets and outlets extending at a 45° angle with respect to the flow direction of the fluid(s) through the flow manifold 50 or inlets and outlets protruding (e.g., extending) from the fluid(s) through the flow manifold 50 in the y-direction. In other embodiments, the inlets and the outlets may extend in different suitable directions from each other (e.g., the +z direction and the −z direction, etc.). The inlets and outlets (e.g., the size, location, protruding direction, etc. of the inlets and outlets) may be suitably varied to meet space requirements in a desired application (e.g., may be suitably designed to fit into a predetermined space). The inlet 105 and outlet 115 may each include a flange, threaded opening, barbed connection, welded joint, etc. for fluid connection to a fluid handling system (e.g., an air conditioning system, a turbocharging system, radiator, heat exchanger, pumped fluid loop, and/or the like).

### Finned Plate

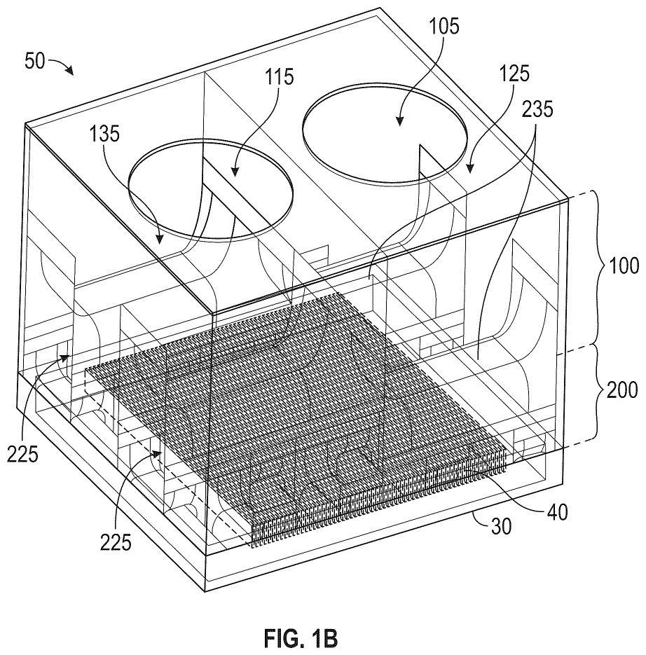

FIG. 2A shows the finned plate 20 of FIG. 1 in more detail. The finned plate 20 includes the base plate 30 and the microchannel array 40 on the base plate 30. The base plate 30 is arranged on an electronic component to be cooled, as explained in more detail herein, and the manifold 50 receives coolant (e.g., from a secondary cooling loop) and discharges heated coolant to the same.

FIG. 2B is an expanded view of FIG. 2A showing a plurality of aligned microchannels 44 and a plurality of fins 42 in the microchannel array 40. The fins 42 are connected to and extend from a surface of the base plate 30, adjacent ones of the fins 42 being spaced apart from each other to form a plurality of microchannels 44 between the fins 42, one of the microchannels 44 being between each adjacent two of the fins 42. An interior of the flow manifold is in fluid communication with the microchannels 44. The microchannels 44 may extend in a direction parallel to each other and perpendicular to a direction of extension of a plurality of first fluid passages in a lowest level of the flow manifold 50. The second level 200 may be the lowest level of the flow manifold 50, but the present disclosure is not limited thereto. In one or more embodiments, the lowest level of the flow manifold 50 may be a third level or a fourth level. Also, as shown in FIG. 2B, the fins 42 are spaced to form the microchannels 44, and may be composed of copper, graphite, and/or other high thermal conductivity materials.

In one or more of embodiments, a width of the microchannels 40 is about 1 micrometer (μm) to about 500 μm, about 5 μm to about 300 μm, or about 20 μm to about 120 μm. It is also understood that these ranges also include all sub-ranges and other ranges beginning and/or ending with any point within these ranges, for example, while the preceding range of about 20 μm to about 120 μm is disclosed, a range of, for example, about 40 μm to about 100 μm is also contemplated and included within the range.

The finned plate 20 may include about 50 to about 500 microchannels 44 that are in parallel alignment to one another.

The fins 42 include a thermally conductive material and may have a highest thermal conductivity axis with a conductivity of at least about 50 watt per meter degree K (W/m-K). In one or more of embodiments, the fins may include aluminum having a thermal conductivity of about 200 W/m-K, copper having a thermal conductivity of about 400 W/m-K, or a copper alloy having a thermal conductivity of about 350 Wm-K to about 400 W/m-K. In one or more of embodiments, the conductivity of the highest thermal conductivity axis of the fins 42 may be about 400 W/m-K to about 3000 W/m-K, about 600 W/m-K to about 1500 W/m-K, or about 800 W/m-K to about 1200 W/m-K. It is also understood that these ranges also include all sub-ranges and other ranges beginning and/or ending with any point within these ranges, for example, while the preceding range of about 800 W/m-K to about 1200 W/m-K is disclosed, a range of, for example, about 900 W/m-K to about 1000 W/m-K is also contemplated and included within the range. The fins 42 may include a protective coating to reduce or prevent corrosion and the protective coating may include nickel, but the present disclosure is not limited thereto.

Aligned graphite has a thermal conductivity in a range of about 1000 W/m-K to about 1,500 W/m-K along its most thermally conductive axis (also referred to as its along-fin axis) compared with silicon, which has a thermal conductivity of about 100 W/m-K. Thus, aligned graphite enables higher fin efficiency (e.g., greater than about 50%) for high-aspect ratio fins (e.g., fins having a greater than 30:1 height to thickness ratio). In some embodiments, the fins 42 may include aligned pyrolytic graphite having a thermal conductivity greater than 1000 W/m-K along the fin axis.

In one or more of embodiments, a thickness of the fins 42 is about 1 μm to about 500 μm, about 5 μm to about 300 μm, or about 20 μm to about 120 μm. It is also understood that these ranges also include all sub-ranges and other ranges beginning and/or ending with any point within these ranges, for example, while the preceding range of about 20 μm to about 120 μm is disclosed, a range of, for example, about 40 μm to about 100 μm is also contemplated and included within the range.

In one or more of embodiments, a height of the fins may be about 200 μm to about 5000 μm, about 400 μm to about 3,500 μm, or about 600 μm to about 1,800 μm. It is also understood that these ranges also include all sub-ranges and other ranges beginning and/or ending with any point within these ranges, for example, while the preceding range of about 600 μm to about 1,200 μm is disclosed, a range of, for example, about 900 μm to about 1000 μm is also contemplated and included within the range.

The base plate 30 has an optimum thickness to accommodate the stress caused when connecting the finned plate 20 to the flow manifold 50. If (e.g., when) the base plate is too thin, the stresses may cause the microchannel arrays to bow and/or curve, which may increase thermal interface resistance between the finned plate and a heat source (e.g., an electronic component). If (e.g., when) the base plate is too thick, the added (unnecessary) material may increase the thermal resistance of solid conduction.

The base plate 30 may include thermal stress mitigating materials that have coefficient of thermal expansion (CTE) matching to the heat source material (e.g., a silicon electronic component) with relatively high compliance. For example, the CTE of CuMo and copper impregnated graphite (POCO) are each similar to silicon and POCO also has a relatively high shear compliance. Thermally induced stress due to CTE mismatch may be lower in POCO than in CuMo. Non-limiting examples of materials suitable for the base plate include CuW, Cu-diamond, Cu—SiC, and Cu—AlN.

The base plate 30 may include at least one metal or metal-containing compound having high thermal conductivity. In some embodiments, the base plate 30 may include aluminum, carbon, copper, gold, molybdenum, nitrogen, palladium, platinum, silicon, silver, tungsten, graphite, diamond, an alloy thereof, a compound thereof, and a (e.g., any suitable) combination thereof. The base plate 30 may be manufactured using skiving, conventional machining (e.g., milling or sawing/cutting), or additive manufacturing (e.g., LBPF, SLS, ECAM, etc.), but the present disclosure is not limited thereto.

The fins 42 and the base plate 30 may be manufactured using the same method or the fins 42 may be fabricated onto a base plate that was previously fabricated using a different method (e.g., additive fins on a conventionally machined base plate). Additional machining may be performed on the finned plate 20 after the fins are formed (e.g., holes drilled, edges cut to shape).

In one or more of embodiments, a thickness of the base plate 30 may be about 10 μm to about 2000 μm, about 100 μm to about 1000 μm, or about 400 μm to about 600 μm. It is also understood that these ranges also include all sub-ranges and other ranges beginning and/or ending with any point within these ranges, for example, while the preceding range of about 250 μm to about 750 μm is disclosed, a range of, for example, about 300 μm to about 400 μm is also contemplated and included within the range.

In one or more of embodiments, a shear modulus of the base plate 30 may be about 10 megapascal (MPa) to about 300 gigapascal (GPa), about 100 MPa to about 100 GPa, or about 1000 MPa to about 5 GPa. It is also understood that these ranges also include all sub-ranges and other ranges beginning and/or ending with any point within these ranges, for example, while the preceding range of about 100 MPa to about 100 GPa, is disclosed, a range of, for example, about 800 MPa to about 80 GPa is also contemplated and included within the range.

### Additional Levels of Flow Manifold

Flow manifold 50 may have no levels other than the first and second levels 100/200, but the present disclosure is not limited thereto. In one or more of embodiments, the flow manifold may include a third level that includes a plurality of first fluid passages each in fluid communication with the first fluid passages 225 in the second level. The third level may include a plurality of second fluid passages each in fluid communication with the second fluid passages 235 in the second level. In one or more of embodiments, a number of the first fluid passages in the third level may be greater than a number of the first fluid passages 225 in the second level. Each of the first fluid passages 225 in the second level may be in fluid communication with the cool fluid inlet 105 and at least one of the first fluid passages in the third level. Each of the second fluid passages 235 in the second level may be in fluid communication with the warm fluid outlet 115 and at least one of the second fluid passages in the third level.

In one or more of embodiments, each of the second fluid passages in the third level may extend under each of the first fluid passages 225 in the second level.

In one or more of embodiments, the first fluid passages in the third level may extend in a first direction that may be substantially the same as the first direction of the first fluid passages 125 of the first level.

In one or more of embodiments, the flow manifold may include a fourth level that includes a plurality of first fluid passages each in fluid communication with the first fluid passages in the third level. The fourth level may include a plurality of second fluid passages each in fluid communication with the second fluid passages in the third level. In one or more of embodiments, a number of the first fluid passages in the fourth level may be greater than a number of the first fluid passages in the third level. Each of the first fluid passages in the third level may be in fluid communication with the cool fluid inlet 105 and at least one of the first fluid passages in the fourth level. Each of the second fluid passages in the third level may be in fluid communication with the warm fluid outlet 115 and at least one of the second fluid passages in the fourth level.

In one or more of embodiments, each of the second fluid passages in the fourth level may extend under each of the first fluid passages in the third level.

In one or more of embodiments, the first fluid passages in the fourth level may extend in a second direction that may be substantially the same as the second direction of the first fluid passages 225 of the second level.

In one or more embodiments, the output level may be in at least one of the first level 100, second level 200, third level, or fourth level of the flow manifold of the present disclosure.

It will be understood that the flow manifold may include at least three hierarchical levels of fluid passages and each level progressively partitions the cool inlet flows from first-to-second-to-third levels and progressively coalesces the warm outlet flows) from third-to-second-to-first levels, but the present disclosure is not limited thereto. In some embodiments, for example, the cool inlet flow(s) from the first level may be partitioned to the third level directly and/or the warm outlet flows from the third level may be coalesced to the first level directly.

### Flowthrough of Manifold/Microchannels

The flow manifold 50, across a plurality of levels (e.g., first level 100, second level 200, third level, and/or fourth level), separates a single inlet flow into a plurality of individual flows to better correspond to the microchannel array 40. Similarly, the flow manifold 50 receives a plurality of individual fluid flows from the microchannel array 40, across the plurality of levels, and coalesces the fluids into a single outlet flow. For example, the first fluid passages 125/225 act to direct (e.g., separate) one fluid flow emanating from the inlet, and the second fluid passages 135/235 act to coalesce the other fluid flow for supply to the outlet. Each increasing level (first-second-third) may have smaller and/or more fluid passages to separate the inlet flow. Each decreasing level (third-second-first) may have larger and/or less fluid passages to coalesce the outlet fluid flow. The plurality of levels organizes and directs warm and cool fluid flows into and from the passages in the flow manifold 50. A fluid impermeable barrier (e.g., solid material), between adjacent warm and cool fluid passages prevents mixing of warm and cool fluids.

The interfacial arrangement of the fluid passages in the final (lowest) level of flow manifold 50 may correspond to the microchannel array 40. For example, the fluid passages in the final (lowest) level may primarily extend substantially perpendicular to the extension direction of the microchannel array 40 or, in contrast, substantially parallel to the extension direction of the microchannel array 40. The present disclosure, however, is not limited thereto. In other embodiments, the fluid passages in the final (lowest) level of flow manifold 50 may extend at about a 45° angle with respect to the extension direction of the microchannel array 40. Further, the fluid passages in the final (lowest) level of flow manifold 50 may have a length and/or width in a range of 0.1 millimeter (mm) to about 1 centimeter (cm) or, in some embodiments, a range of about 0.3 mm to about 5 mm.

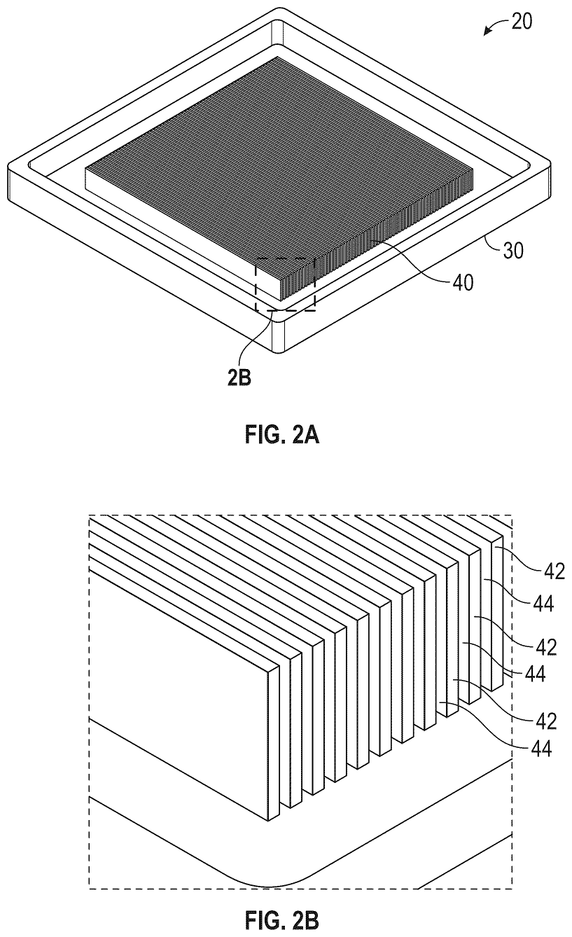

FIG. 3A shows fluid passages 225/235 in second level 200 extending perpendicular to the extension direction of the microchannel array 40. For flow manifold 50 having only first and second levels 100/200, the first fluid passage(s) 125 in first level 100 direct and separate fluid flowing from cool fluid inlet 105 into the first fluid passages 225 in second level 200, which is a final (lowest) level. The downwardly pointing white arrows represent cool fluid flows 32 in the first fluid passages 225, which are directed into the microchannel array 40 where two adjacent fins 42 separate a portion of the cool fluid in a first fluid passage 225 to form a single cool fluid flow 32 in a microchannel 44.

FIG. 3B is a cross sectional view of the interior of a microchannel 44 viewed from the perspective labeled “3B” in FIG. 3A. A lengthwise oriented fin 42 is shown in the background of FIG. 3B. Curved arrows show a typical flow path for cool fluid flows 32 (white arrows) entering a microchannel 44, absorbing heat, and exiting as warm fluid flows 33 (gray arrows). The width of a microchannel 44 (distance between two adjacent fins 42) is limited to be at most about 500 μm and acts to confine a single cool fluid flow 32 to a relatively “short flow path” and forces it to reverse direction and travel out of the microchannel 44. The phrase “short flow path” as used herein, refers to the distance traveled by the coolant fluid in a fluid passage as described in more detail herein. Also, for example, the curved arrows in FIG. 3B illustrate the reversal of coolant flow within the microchannel 44, which enhances heat absorption and minimizes (reduces) thermal resistance.

As the direction of the cool fluid flows 32 is reversed, they absorb heat and transform into warm fluid flows 33, represented as upwardly pointing arrows in FIG. 3A, which are then directed out of the microchannel array 40 and into the second first fluid passages 235 of the second level 200. The heat may be absorbed from the base plate 30 and the fins 42 of the microchannel array 40. The second fluid passages 235 collect the warm fluid flows 33 directed out of the microchannel array 40 and the second fluid passages 135 in first level 100 coalesce the warm fluid flows into the warm fluid outlet 115.

### Specific Flow Manifold Symmetries

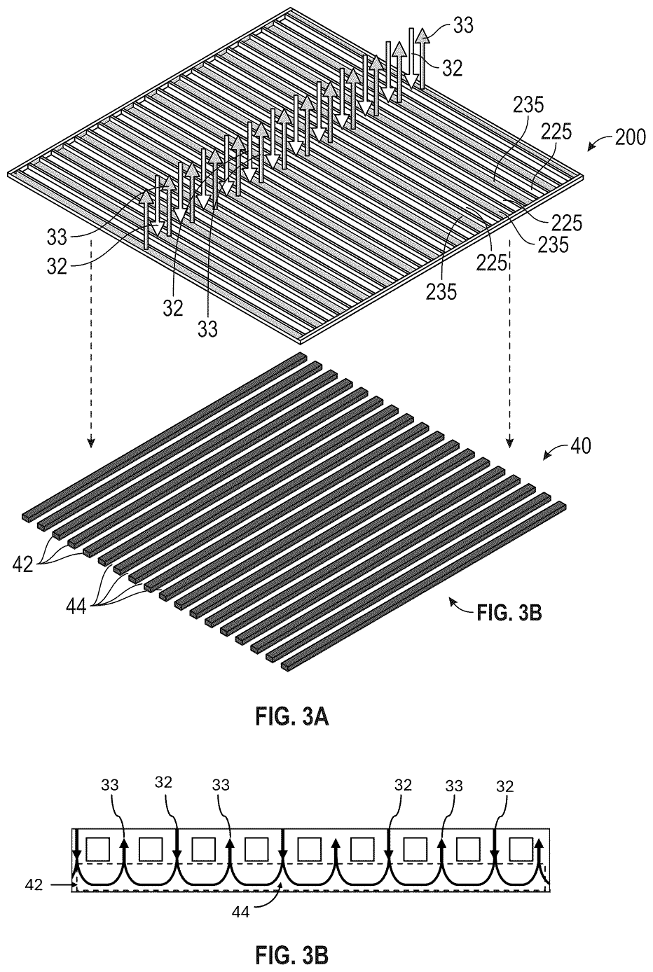

One or more aspects of embodiments of the present disclosure are directed toward flow manifolds with a certain symmetric geometry. FIG. 4 is a schematic diagram of a simple “balancing reference” of a symmetric flow manifold for the cooling apparatus and illustrates a central intake, two peripheral intakes, and two outputs arranged symmetrically about a vertical plane of symmetry. Arrows indicate the direction of coolant flow from the intakes to the outputs. The symmetry plane bisects the central intake and aligns with the flow direction, ensuring balanced distribution and collection of coolant. The configuration shown in FIG. 4 ensures that the flow paths from the intakes to the outputs are geometrically and hydraulically balanced, promoting uniform flow distribution across the microchannel array. The symmetry enhances thermal performance and reduces pressure differentials within the cooling apparatus.

In one or more embodiments, a forked flow manifold includes a first level that is an output level and includes first fluid passages open to an inlet and second fluid passages open to an outlet. The forked flow manifold includes a second level including first fluid passages and second fluid passages. The first fluid passages in the first level of the forked manifold include a central intake, two periphery intakes, and n median intakes. The second fluid passages in the first level of the forked manifold include n+2 outputs. The variable “n” may be an integer from 0 to 10.

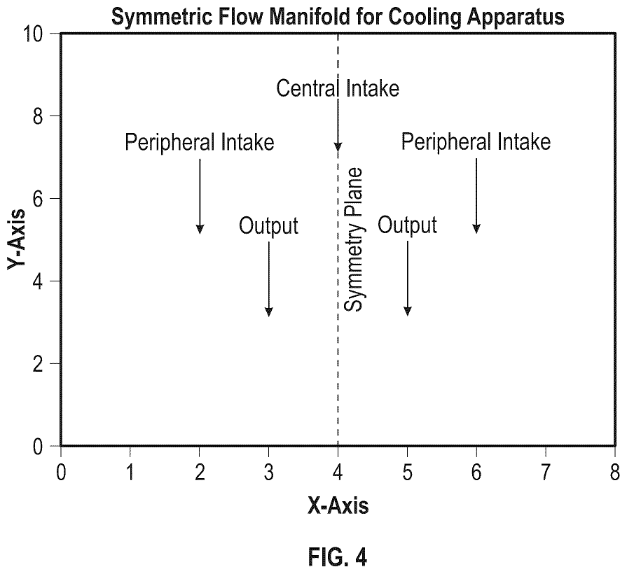

FIG. 5 shows a forked flow manifold 500 where n is 0 and including a first level 510 having a cool fluid inlet 505 (e.g., region rendered in white) and a warm fluid outlet 515 (e.g., region rendered in gray). Here, reference to “warm” and “cool” is only for ease of explanation, and terms can be replaced by “first” and “second” without affecting the disclosure. For example, the flow direction through forked flow manifold 500 may be reversed to provide substantially the same performance with the cool incoming coolant passing through the gray region and the warm outgoing coolant passing through the white region. In one or more embodiments, the forked flow manifold 500 may include a plurality of (at least one) cool fluid inlets and a plurality of (at least one) warm fluid outlets.

The forked flow manifold 500 has a plane of symmetry SP.FFM that bisects forked flow manifold 500 and divides its structures to be mirrored on either side of SP.FFM. A flow rate and/or volume of the cool fluid inlet 505 and a flow rate and/or volume of the warm fluid outlet 515 may be substantially equal with respect to the plane of symmetry SP.FFM.

FIG. 5 shows that forked flow manifold 500 includes a central intake 512 at a center of the first level 510, and two periphery intakes 516 at opposite ends of the first level 510. The first level 510 of forked flow manifold 500 includes two outputs 519 each between the central intake 512 and one of the periphery intakes 516. For example, the forked flow manifold 500 shown in FIG. 5 illustrates the configuration of central intake 512, periphery intakes 516, and outputs 519, arranged symmetrically about plane SP.FFM.

In one or more embodiments, each output 519 may have a width that is substantially equal to the other and substantially equal to a width of the central intake 512. In one or more embodiments, the width of each output 519 may be about twice a width of any one periphery intake 516.

The plane of symmetry SP.FFM of forked flow manifold 500 bisects the central intake 512 and may be substantially parallel to a flow direction of the central intake 512. In one or more embodiments, the volume and/or flowrate of the central intake 512 may be distributed equally around the plane of symmetry SP.FFM. In one or more embodiments, the periphery intakes 516 are spatially distributed equally around the plane of symmetry SP.FFM, and the outputs 519 are spatially distributed equally around the plane of symmetry SP.FFM. In one or more embodiments, the volume and/or flowrate of each periphery intake 516 may be substantially the same, and the volume and/or flowrate of each output 519 may be substantially the same.

FIG. 5A is a partial cut-away view of the forked flow manifold 500 showing a second level 520 that includes first fluid passages 523 and second fluid passages 526. Each of the first fluid passages 523 may be in fluid communication with the central intake 512 and the periphery intakes 516. Each of the second fluid passages 526 may be in fluid communication with the outputs 519.

### Additional Features

According to one or more embodiments of the present disclosure, the cooling apparatus may include a compression gasket and each of the finned plate and the flow manifold may have a sealing groove. The dimensions of the sealing groove may be iteratively optimized to provide sufficient sealing while also minimizing gasket compression-induced stresses, e.g., on the fins and/or the finned plate. The compression gasket may be an o-ring gasket and the sealing groove may be a recessed groove suitable for use with the o-ring gasket but the present disclosure is not limited thereto.

The compression gasket (e.g., o-ring gasket) may be or include rubber, silicone, other elastomeric materials, and/or a (e.g., any suitable) combination thereof. In some embodiments, the compression gasket may be a flat gasket or may be a formed-in-place gasket.

The finned plate may be coupled to the flow manifold with a bond interface such as a brazed bond, a soldered bond, an adhesive (e.g., epoxy) bond, a fusion bond, and/or a (e.g., any suitable) combination thereof. In one or more embodiments, the finned plate and the flow manifold may be fabricated as a single component and include a compression gasket and/or bond interface.

According to one or more embodiments of the present disclosure, the cooling apparatus may include an air gap between the finned plate and the flow manifold. Differences in thermal expansion characteristics of the two components may result in uneven expansion of the two components that results in lateral stress, bending, delamination, and/or the like. The air gap enables the finned plate and the flow manifold to expand independently, thereby reducing mechanical stress.

The air gap may be continuous or segmented, and may be formed by spacers, ridges, or molded features in the manifold or bracket. In some embodiments, the air gap may be filled with a compliant material such as silicone foam, elastomeric foam, or inert gas to provide vibration damping while still allowing thermal expansion.

According to one or more embodiments of the present disclosure, the flow manifold includes flow dividers configured to partition an input flow into flow stream sections. The flow dividers may be oriented vertically and/or horizontally and may be spaced apart at a distance that is regular, area preserving, or flowrate preserving. The flow dividers may include the same material from which the flow manifold is manufactured and may be flat and/or fin-shaped.

In one or more embodiments, each of the flow stream sections may have a substantially equal flowrate.

The flow dividers may be configured to modulate a Reynolds number of the flow stream sections. In some embodiments, the flow stream sections have a laminar flow. In one or more embodiments, the flow dividers are shaped to induce secondary flow structures that enhance convective heat transfer while maintaining laminar flow conditions.

In some embodiments, a space between two adjacent of the flow dividers may be an integral of a Poiseuille distribution of the flow stream.

According to one or more embodiments of the present disclosure, the flow manifold may include internal flow-shaping structures having shapes that streamline fluid flow, reduce vortex formation, promote laminar flow, and/or reduce turbulence. In some embodiments, the flow-shaping structures may be at least one selected from among airfoil-shaped vanes (e.g., airfoils or hydrofoils), flow dividing ribs, wing-shaped vanes, arrays of posts, arrays of tubes, truss structures, fins, curved fins, streamlined baffles and steps. In some embodiments, the flow-shaping structures may reduce pressure drop, improve flow uniformity, and/or enhance thermal performance.

In some embodiments, the flow-shaping structures may be positioned to align with the direction of fluid flow. For example, the flow-shaping structures may not be fixed in place and may rotate to align with the direction of fluid flow. In some embodiments, the flow-shaping structures may be additively manufactured as part of the manifold body.

One or more aspects of embodiments of the present disclosure are directed toward a cooling system including at least one cooling apparatus including a finned plate and a flow manifold as described herein, at least one pump, and at least one heat exchanger in fluid communication with the flow manifold of the cooling apparatus.

One or more aspects of embodiments of the present disclosure are directed toward a cooling system including an electronic component, a cooling apparatus as described herein on the electronic component, and a heat exchanger in fluid communication with the flow manifold of the cooling apparatus. The electronic component may include a semiconductor chip and/or an integrated circuit but the present disclosure in not limited thereto.

One or more aspects of embodiments of the present disclosure are directed toward a systems-level integrated cooling system including a plurality of cooling apparatuses each as described herein, a shared coolant distributor configured to supply a coolant to each of the plurality of cooling apparatus, a controller configured to monitor and adjust coolant flow rates to each of the plurality of cooling apparatuses based on thermal load, and a heat exchanger in fluid communication with the shared coolant distributor.

A coolant used in the cooling systems, cooling apparatus, finned plate, and flow manifold of the present disclosure may be a single-phase coolant, a two-phase coolant, or a combination thereof. The coolant may include water, ethylene glycol, propylene glycol, oils, air, refrigerants, halocarbons, and/or one or more (e.g., any suitable) combinations thereof.

In some embodiments, the coolant flowing in the cooling apparatus, finned plate, and/or flow manifold and/or between the cooling apparatus and the heat exchanger may have a laminar flow or a non-laminar flow.

One or more aspects of embodiments of the present disclosure are directed toward a data center including a plurality of electronic components, at least one cooling system according to present disclosure, where the plurality of cooling apparatuses are on the plurality of electronic components.

In one or more embodiments, a method of fabricating a cooling apparatus, includes: (a) additively manufacturing a flow manifold having a symmetric multiscale hierarchical flow routing structure, or a multiscale hierarchical flow routing structure defined with respect to a balancing reference; (b) forming a finned plate including a base plate and a plurality of fins; and (c) coupling the flow manifold to the finned plate to form a cooling apparatus configured to remove multi-kilowatt thermal loads from a chip-scale surface area.

In one or more embodiments, a cooling apparatus includes a finned plate including a base plate and a microchannel array, and a flow manifold including a first level including first fluid passages open to an inlet, an output level including second fluid passages open to an outlet, and a second level including first and second fluid passages, wherein the flow manifold is defined by a balancing reference such that the volume of the inlet and the volume of the outlet are substantially equal with respect to the balancing reference. The cooling apparatus may be fabricated by a method including additively manufacturing the flow manifold and the finned plate as a single integrated structure, and post-processing the internal flow passages to improve surface finish and flow uniformity. This integrated fabrication approach enables precise alignment of the manifold and microchannel features, reduces interfacial thermal resistance, and supports complex geometries that enhance thermal and hydraulic performance.

The following examples and experimental data are provided for illustrative purposes only, and do not limit the scope of one or more embodiments of the present disclosure.

### EXAMPLES

### Example 1

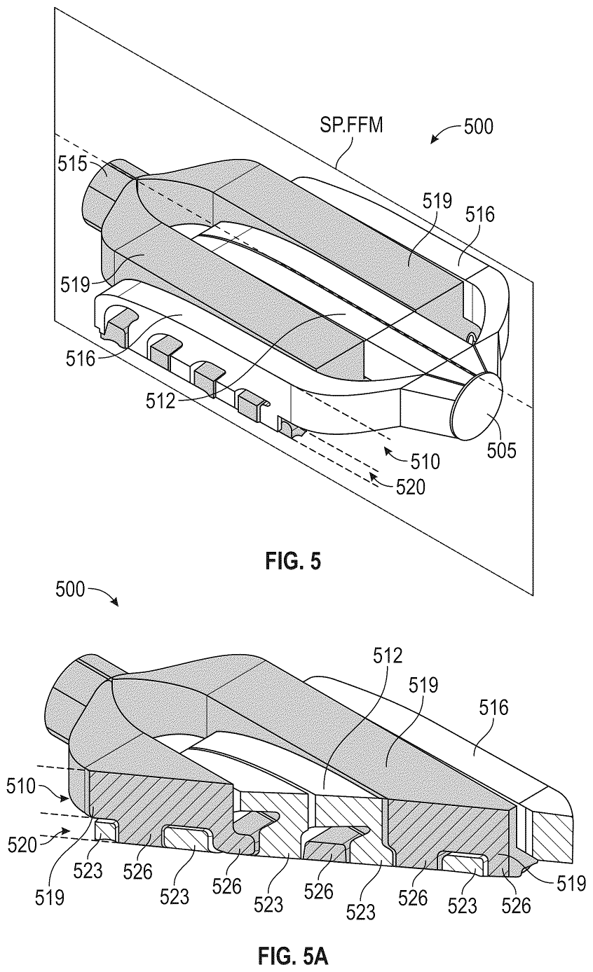

FIG. 6 shows flow manifold 600 that was manufactured using an additive manufacturing process according to the present disclosure. Flow manifold 600 has a plane of symmetry SP.600 that bisects flow manifold 600 and divides its structures to be mirrored on either side of SP.600.

FIG. 6A is a cross sectional view of flow manifold 600 showing a cool fluid inlet 605 and a warm fluid outlet 615. The cool fluid inlet 605 is in fluid communication with a first fluid passage 625 that is in fluid communication with first fluid passages 652 at the bottom of flow manifold 600. Second fluid passages 654 at the bottom of flow manifold 600 are interleaved with first fluid passages 652 and are in fluid communication with the second fluid passages 635 that curve laterally around flow manifold 600 and coalesce into plenum 640 that is in fluid communication with the warm fluid outlet 615.

FIG. 6B shows a cut-away view of the flow manifold 600 that includes fanned flow dividers 642 that coalesce outlet flow stream sections each having a substantially equal flow rate into warm fluid outlet 615. A distance between two adjacent fanned flow dividers 642 may be determined according to a Poiseuille distribution to improve flow uniformity. The flow manifold 600 includes parallel flow dividers 644 that act to reduce turbulence of the flow stream sections, e.g., reduce the Reynolds number of the flow stream sections. For example, in a cooling apparatus, the flow manifold 600 includes the fanned flow dividers 642 and the parallel flow dividers 644 configured to partition and condition flow, as shown in FIG. 6B. The fanned flow dividers 642 are spaced according to a Poiseuille distribution to ensure equal flow partitioning, while the parallel flow dividers 644 reduce turbulence and maintain laminar flow.

A distance between two adjacent flow dividers may be flowrate preserving and may act to modulate a circular cross section of the input flow (e.g., from cool fluid inlet 605) to some other arbitrary profile via a lofted flow section. In this case, the distance (Δx=xᵢ₊₁−xᵢ) between two adjacent fanned flow dividers 642 may be determined by integrating Equation 1 (Poiseuille distribution) over the cross-sectional area:

$$Q ( {x}_{i} , {x}_{i + 1} ) = 4 {\int }_{{x}_{i}}^{{x}_{i + 1}} {\int }_{0}^{\sqrt{{R}^{2} - {x}^{2}}} u ( x , y ) dydx \qquad Equation 1$$

where Q is the flowrate between two adjacent flow dividers positioned at coordinates xᵢ and xᵢ₊₁, R is the internal pipe radius, x is the horizontal coordinate direction, y is the vertical coordinate direction, and x and y are related by Equation 2:

$$u ( x , y ) = {u}_{0} ( 1 - \frac{{x}^{2} + {y}^{2}}{{R}^{2}} ) , \qquad Equation 2$$

with u0 being the maximum velocity. The double integral is evaluated for progressive pairings of flow divider coordinates xᵢ and xᵢ₊₁ that yield equivalent values of Q. Flow divider spacing (e.g., distance between two adjacent flow dividers) at the manifold-loft interface must be determined or designed separately to correspond as needed. The distance between two adjacent flow dividers may also be determined via iteration using CFD and/or via a normalized (by pipe radius and maximum flow velocity) lookup table of previously computed values.

### Example 2: Performance Evaluation

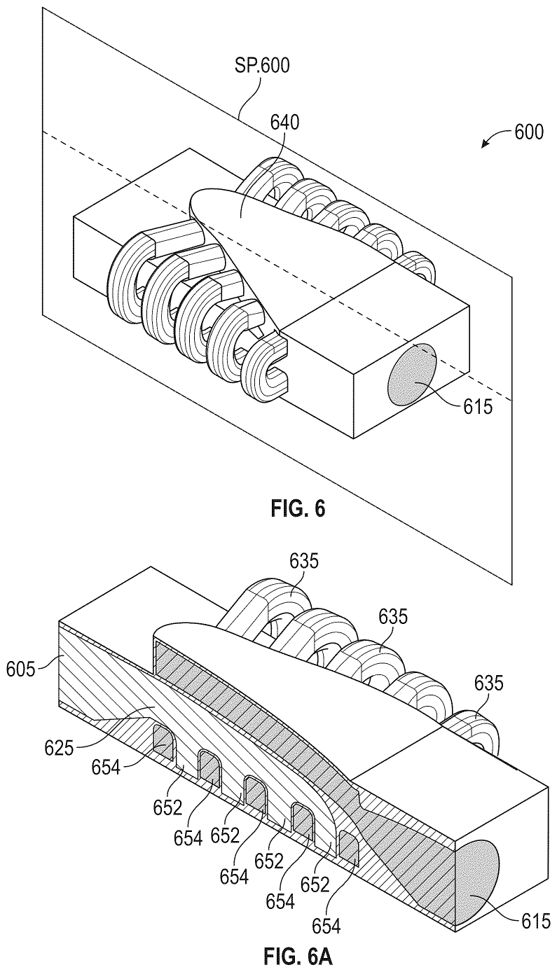

FIGS. 7-9 display the performance evaluation of a cooling apparatus according to the present disclosure that had a heat transfer area of 10.6 square centimeter (cm²) and included a flow manifold 600 as described in Example 1.

FIG. 7 shows the results for resistance measured against efficiency.

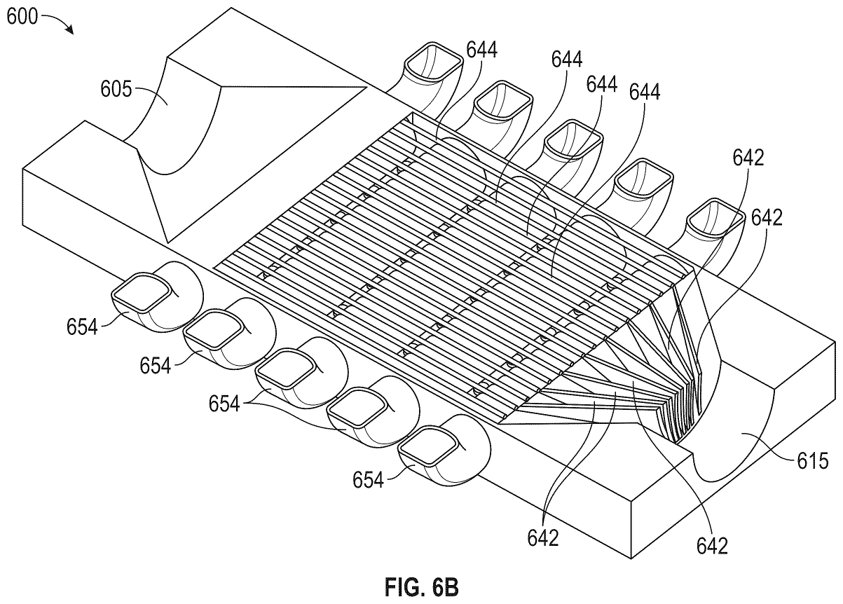

FIG. 8 shows the results for pressure drop measured against flow rate (i.e., flow efficiency).

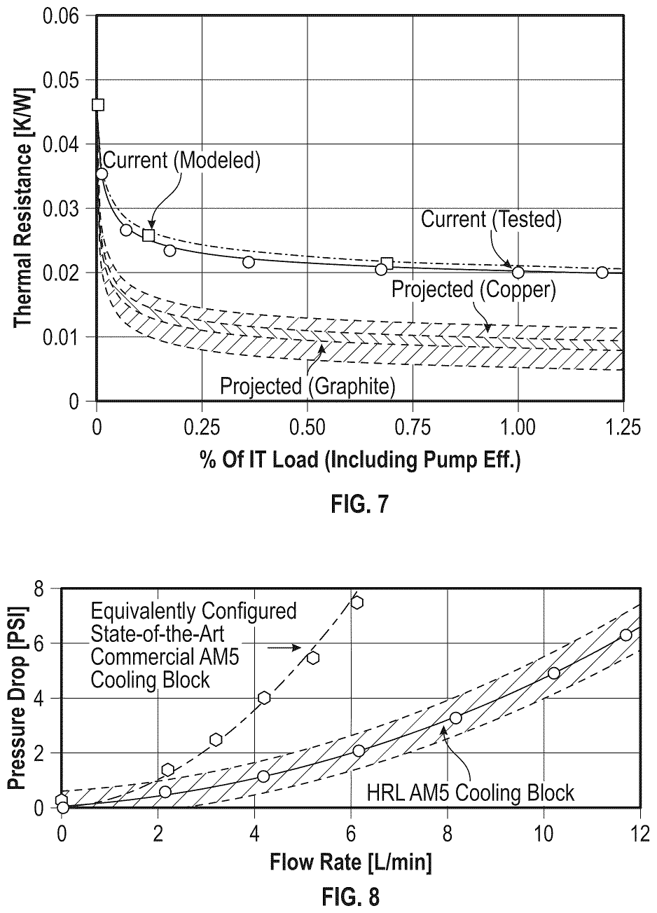

FIG. 9 shows the results for maximum power measured against efficiency within a temperature differential of about 40° C.

### Example 3

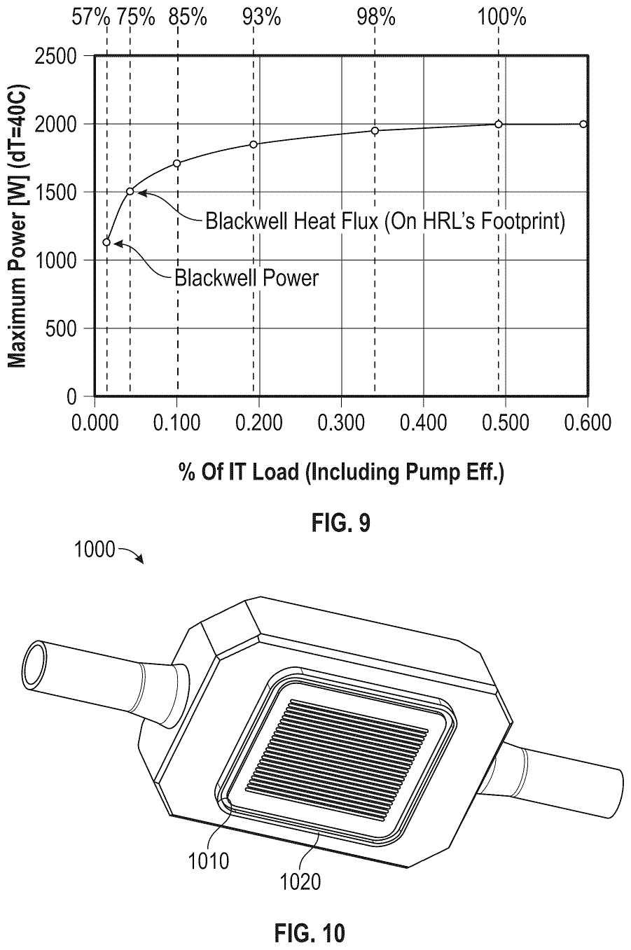

FIG. 10 shows a flow manifold 1000 that was manufactured using an additive manufacturing process according to the present disclosure and includes an o-ring groove 1010 in an interface extrusion 1020. A mounting bracket may be coupled to the interface extrusion 1020 and then used to mount a flow manifold according to the present disclosure to a finned plate to provide a cooling apparatus according to the present disclosure. For example, in a cooling apparatus, the flow manifold 1000 includes the interface extrusion 1020 including the o-ring groove 1010, as shown in FIG. 10.

Terms such as “substantially,” “about,” and “~” are utilized as terms of approximation and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all sub-ranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

While the present disclosure has been described in connection with certain example embodiments, it is to be understood that the present disclosure is not limited to the disclosed embodiments, but, on the contrary, is intended to cover various modifications and equivalent arrangements included within the spirit and scope of the claims, and equivalents thereof.

The annotations used in FIGS. 1-3B, 5-6B and 10 are listed hereafter.

10: cooling apparatus
20: finned plate
30: base plate
32: cool fluid flow
33: warm fluid flow
40: microchannel array
42: fin
44: microchannel
50: flow manifold
100: first level
105: cool fluid inlet
115: warm fluid outlet
125: first fluid passages
135: second fluid passages
150: output level
200: second level
225: first fluid passages
235: second fluid passages
500: forked flow manifold
510: first level
505: cool fluid inlet
512: central intake
515: warm fluid outlet
516: periphery intake
519: output
520: second level
523: first fluid passages
526: second fluid passages
600: flow manifold
605: cool fluid inlet
615: warm fluid outlet
625: first fluid passage
635: second fluid passages
640: plenum
642: fanned flow dividers
644: parallel flow dividers
652: first fluid passages
654: second fluid passages
SP.1: plane of symmetry
SP.FFM: plane of symmetry
SP.600: plane of symmetry

What is claimed is:

1. A cooling apparatus comprising:
a finned plate comprising a base plate and a microchannel array; and
a flow manifold comprising:
a first level comprising first fluid passages open to an inlet;
an output level comprising second fluid passages open to an outlet;
a second level comprising first fluid passages and second fluid passages; and
a balancing reference,
a volume of the inlet and a volume of the outlet being substantially equal with respect to the balancing reference.

2. The cooling apparatus of claim 1, wherein the microchannel array comprises a plurality of fins, the fins being connected to and extending from a surface of the base plate, adjacent ones of the fins being spaced apart from each other to form a plurality of microchannels between the fins, one of the microchannels being between each adjacent two of the fins, and
wherein an interior of the flow manifold is in fluid communication with the microchannels.

3. The cooling apparatus of claim 2, wherein the microchannels extend in a direction parallel to each other and perpendicular to a direction of extension of a plurality of first fluid passages in a lowest level of the flow manifold.

4. The cooling apparatus of claim 2, wherein a width of the microchannels is about 1 micrometer (μm) to about 500 μm.

5. The cooling apparatus of claim 2, wherein the fins comprise a thermally conductive material and have a highest thermal conductivity axis with a conductivity of at least about 400 watt per meter degree K (W/m-K),
a thickness of the fins is about 1 μm to about 500 μm, and
a height of the fins is about 200 μm to about 5000 μm.

6. The cooling apparatus of claim 1, wherein
the base plate comprises aluminum, carbon, copper, gold, molybdenum, nitrogen, palladium, platinum, silicon, silver, tungsten, graphite, diamond, an alloy thereof, a compound thereof, and any suitable combination thereof,
a thickness of the base plate is about 10 μm to about 2000 μm, and
a shear modulus of the base plate is about 10 megapascal (MPa) to about 300 gigapascal (GPa).

7. The cooling apparatus of claim 1, wherein
each of the first fluid passages in the second level is in fluid communication with the inlet via the first fluid passages in first level,
each of the second fluid passages in the second level is in fluid communication with the outlet via the second fluid passages in the first level,
the first fluid passages in the second level are greater in number than the first fluid passages in the first level,
the first fluid passages in the first level extend in a first direction,
the first fluid passages in the second level extend in a second direction, the second direction perpendicular to and crossing the first direction,
each of the first fluid passages in the second level extend under the first fluid passages in the first level.

8. The cooling apparatus of claim 1, wherein the first fluid passages in the second level are interleaved with the second fluid passages in the second level.

9. The cooling apparatus of claim 1, wherein
the flow manifold comprises a third level comprising a plurality of first fluid passages and a plurality of second fluid passages, a number of the first fluid passages in the third level being greater than a number of the first fluid passages in the second level,
each of the first fluid passages in the second level is in fluid communication with the inlet and at least one of the first fluid passages in the third level, and
each of the second fluid passages in the second level is in fluid communication with the outlet and at least one of the second fluid passages in the third level.

10. The cooling apparatus of claim 1, wherein the flow manifold comprises a forked flow manifold, and wherein,
the first level is the output level,
the first fluid passages comprise a central intake, two periphery intakes, and n median intakes, the central intake at a center of the first level, the periphery intakes at opposite ends of the first level, and each of the median intakes between the central intake and one of the periphery intake,
the second fluid passages comprise n+2 outputs, each output between the central intake and one of the periphery intakes, and each having a width that is substantially equal,
n is an integer from 0 to 10,
the balancing reference is a plane of symmetry bisecting the central intake and parallel to a flow direction of the central intake,
the width of each output is substantially equal to a width of the central intake, and about twice a width of any one periphery intake,
each of the first fluid passages in the second level is in fluid communication with the central intake, the periphery intakes, the n median intakes, and
each of the second fluid passages in the second level is in fluid communication with the n+2 outputs.

11. The cooling apparatus of claim 1, wherein the flow manifold is configured to provide symmetric flow distribution, and
wherein the flow manifold and the finned plate are modular and removably coupled.

12. The cooling apparatus of claim 1, wherein the cooling apparatus comprises a compression gasket and each of the finned plate and the flow manifold comprises a sealing groove.

13. The cooling apparatus of claim 1, wherein the flow manifold comprises a thermal isolation layer between the inlet and the outlet, the thermal isolation layer comprising a gas-filled cavity, aerogel, or a low-conductivity polymer.

14. The cooling apparatus of claim 1, wherein the balancing reference comprises a mirror plane of symmetry bisecting the flow manifold, the inlet and the outlet being mirrored through the mirror plane of symmetry.

15. The cooling apparatus of claim 1, wherein the balancing reference comprises a rotational axis of symmetry about which the inlet and the outlet are arranged in a radially symmetric configuration.

16. A cooling system comprising:
at least one cooling apparatus comprising
a finned plate comprising a base plate and a microchannel array; and
a flow manifold comprising:
a first level comprising first fluid passages open to an inlet;
an output level comprising second fluid passages open to an outlet;
a second level comprising first fluid passages and second fluid passages; and
a balancing reference, a volume of the inlet and a volume of the outlet being substantially equal with respect to the balancing reference,
at least one pump; and
at least one heat exchanger in fluid communication with the flow manifold of the cooling apparatus.

17. The cooling system of claim 16, wherein the cooling system comprises:
an electronic component;
the cooling apparatus on the electronic component; and
a heat exchanger in fluid communication with the flow manifold of the cooling apparatus.

18. The cooling system of claim 16, wherein the cooling system comprises:
a plurality of cooling apparatuses;
a shared coolant distributor configured to supply a coolant to each of the plurality of cooling apparatus;
a controller configured to monitor and adjust coolant flow rates to each of the plurality of cooling apparatuses based on thermal load; and
a heat exchanger in fluid communication with the shared coolant distributor.

19. The cooling system of claim 18, wherein a coolant flows between the cooling apparatus and the heat exchanger, and the coolant has a laminar flow.

20. A data center comprising:
a plurality of electronic components; and
at least one cooling system according to claim 18;
wherein the plurality of cooling apparatuses are on the plurality of electronic components.
